(19) United States
(12) Patent Application Publication
(10) Pub. No.: US 2024/0263300 A1
(43) Pub. Date: Aug. 8, 2024

(54) CONTROL SYSTEM OF DEPOSITION SOURCE

(71) Applicant: Samsung Display Co., LTD., Yongin-si (KR)

(72) Inventors: Yeong-Min KIM, Yongin-si (KR); Shinyang KIM, Yongin-si (KR); Bogeom KIM, Yongin-si (KR)

(73) Assignee: Samsung Display Co., LTD., Yongin-si (KR)

(21) Appl. No.: 18/519,545

(22) Filed: Nov. 27, 2023

(30) Foreign Application Priority Data
Feb. 8, 2023 (KR) 10-2023-0016882

(51) Int. Cl. C23C 14/54; C23C 16/52

(52) U.S. Cl. CPC C23C 14/545; C23C 16/52

(57) ABSTRACT

A control system of a deposition source includes a deposition source that includes a heater and provides a deposition material on a substrate, a sensor that detects an amount of the deposition material provided to the substrate, a rate calculator that calculates a first deposition rate based on the amount of the deposition material provided to the substrate, and a filter that calculates a second deposition rate by removing a noise from the first deposition rate. The control system of the deposition source may improve deposition quality by a stabilized signal by removing noise.

### CROSS-REFERENCE TO RELATED APPLICATION(S)

This application claims priority to and benefits of Korean Patent Application No. 10-2023-0016882 under 35 U.S.C. § 119, filed on Feb. 8, 2023, in the Korean Intellectual Property Office (KIPO), the entire contents of which are incorporated herein by reference.

### BACKGROUND

### 1. Technical Field

Embodiments relate to a control system of a deposition source that provides a stabilized control signal.

### 2. Description of the Related Art

A display device may include multiple thin films. Each of the thin films may be formed by a vacuum deposition method, an ion plating method, a physical vapor deposition method, a chemical vapor deposition method, or the like.

A deposition apparatus for performing the vacuum deposition method may include a deposition source. The deposition source may include a crucible that stores a deposition material, a heater that heats the crucible, a nozzle that ejects the deposition material, or the like.

When a temperature of the heater is out of a predetermined range, a film thickness of each of the thin films may deviate from a reference thickness. For example, when the temperature of the heater is excessively high, the film thickness may be formed thicker than the reference thickness. On the other hand, when the temperature of the heater is excessively low, the thickness of the film may be smaller than the reference thickness.

### SUMMARY

The disclosure may provide a control system of a deposition source.

The technical objectives to be achieved by the disclosure are not limited to those described herein, and other technical objectives that are not mentioned herein would be clearly understood by a person skilled in the art from the description of the disclosure.

A control system of a deposition source according to an embodiment of the disclosure may include a deposition source that includes a heater and provides a deposition material to a substrate, a sensor that detects an amount of the deposition material provided to the substrate, a rate calculator that calculates a first deposition rate based on the amount of the deposition material provided to the substrate, and a filter that calculates a second deposition rate by removing a noise from the first deposition rate.

In an embodiment, the sensor may be a quartz crystal microbalance (QCM).

In an embodiment, the filter may be a median filter.

In an embodiment, the filter may remove the noise in case that the first deposition rate is outside of a predetermined range.

In an embodiment, the control system of the deposition source may further include a first controller that generates a control signal based on the second deposition rate.

In an embodiment, the first controller may be a proportional integral derivative (PID) control-type controller.

In an embodiment, the control signal may control an amount of power supplied to the heater.

In an embodiment, the filter and the first controller may be implemented in a same device.

In an embodiment, the control system of the deposition source may further include a second controller that stores a reference rate and provides the reference rate to the first controller.

In an embodiment, the second controller may be a programmable logic controller (PLC).

A control system of a deposition source according to an embodiment of the disclosure may include a deposition source that includes a heater and provides a deposition material to a substrate, a sensor that detects an amount of the deposition material provided to the substrate, a rate calculator that calculates a first deposition rate based on the amount of the deposition material provided to the substrate, a filter that calculates a second deposition rate by removing a noise from the first deposition rate, and a first controller that compares the second deposition rate with a reference rate and generates a control signal controlling an amount of power supplied to the heater.

In an embodiment, the sensor may be a quartz crystal microbalance (QCM).

In an embodiment, the filter may be a median filter.

In an embodiment, the filter may remove the noise in case that the first deposition rate is outside of a predetermined range.

In an embodiment, the first controller may generate the control signal based on the second deposition rate in case that the first deposition rate is outside of the predetermined range.

In an embodiment, the first controller may generate the control signal based on the first deposition rate in case that the first deposition rate is within the predetermined range.

In an embodiment, the first controller may be a proportional integral derivative (PID) control-type controller.

In an embodiment, the filter and the first controller may be implemented in a same device.

In an embodiment, the control system of the deposition source may further include a second controller that stores the reference rate and provides the reference rate to the first controller.

In an embodiment, the second controller may be a programmable logic controller (PLC).

In a control system of a deposition source according to an embodiment of the disclosure, a control system of a deposition source may include a deposition source that includes a heater and provides a deposition material to a substrate, a sensor that detects an amount of the deposition material provided to the substrate, a rate calculator that calculates a first deposition rate based on the amount of the deposition material provided to the substrate, and a filter that calculates a second deposition rate by removing a noise from the first deposition rate. Accordingly, a control signal may be stabilized.

In addition, the control system of the deposition source may calculate a second deposition rate in case that the first deposition rate is outside of a predetermined range. Accordingly, the control system of the deposition source may stabilize the control signal, and at the same time the control system of the deposition source may prevent a control delay due to a noise removal process.

### BRIEF DESCRIPTION OF THE DRAWINGS

FIG. 1 is a schematic block diagram illustrating a control system of a deposition source according to an embodiment of the disclosure.

FIG. 2 is a schematic cross-sectional view illustrating the deposition source included in the control system of FIG. 1.

FIG. 3 is a schematic block diagram illustrating an operation of the control system of the deposition source according to an embodiment.

FIG. 4 is a schematic block diagram illustrating an operation of the control system of the deposition source according to another embodiment.

FIG. 5 is a graph illustrating the first deposition rate provided by the rate calculator included in the control system of the deposition source of FIG. 1.

FIG. 6 is a graph illustrating the second deposition rate provided by the filter included in the control system of the deposition source of FIG. 1.

FIG. 7 is a schematic block diagram of a control system of the deposition source according to another embodiment of the disclosure.

FIG. 8 is a flowchart of the control method of the deposition source using the control system of the deposition source according to embodiments of the disclosure.

FIG. 9 is a schematic cross-sectional view illustrating a pixel formed by the deposition process using the deposition apparatus including the control system 1A of the deposition source 40 or 1B according to embodiments of the disclosure.

### DETAILED DESCRIPTION OF THE EMBODIMENTS

Hereinafter, disclosure in accordance with embodiments will be described in more detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

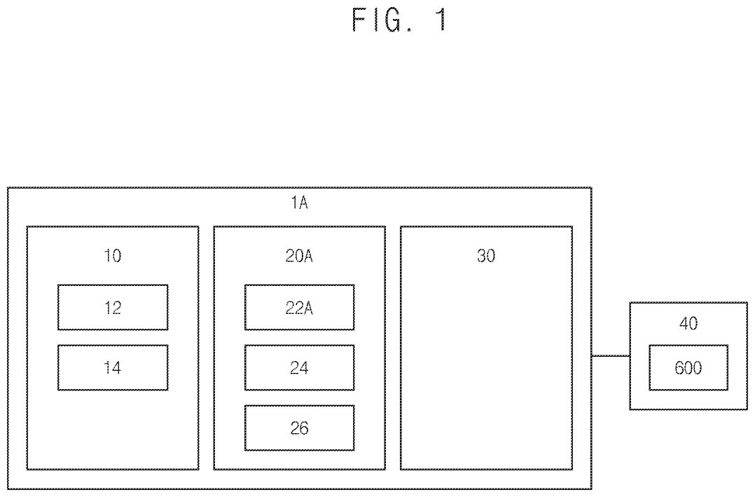

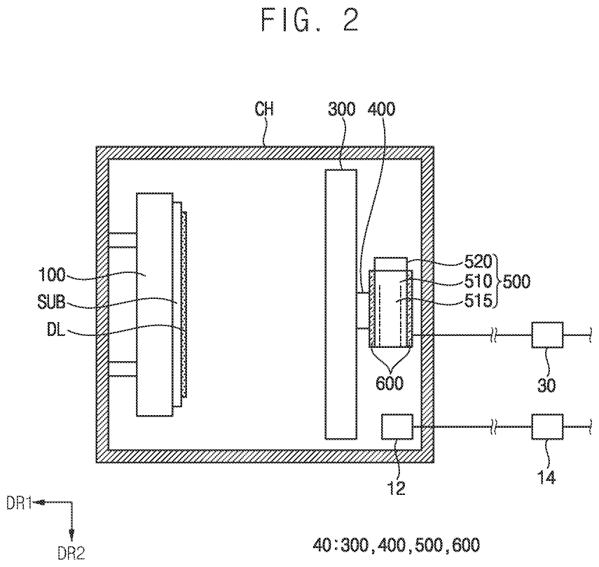

FIG. 1 is a schematic block diagram illustrating a control system of a deposition source according to an embodiment of the disclosure. FIG. 2 is schematic a cross-sectional view illustrating the deposition source included in the control system of FIG. 1.

Referring to FIGS. 1 and 2, a control system 1A of a deposition source 40 according to an embodiment of the disclosure may include the deposition source 40, a monitoring part 10 connected to the deposition source 40, a control part 20A, and a power supply 30.

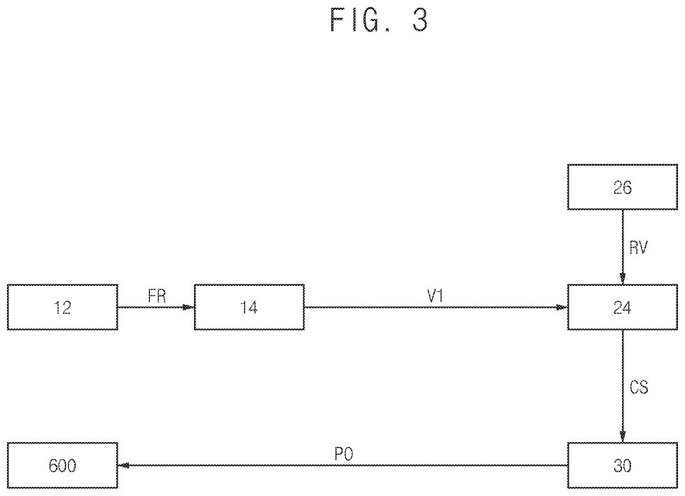

The monitoring part 10 may monitor a thickness of a deposition film DL. The thickness of the deposition film DL may be defined as an amount of deposition material deposited on a substrate SUB per unit time. Hereinafter, the thickness of the deposition film DL may be referred to as a first deposition rate (e.g., a first deposition rate V1 of FIG. 3). The monitoring part 10 may include a sensor 12 and a rate calculator 14.

The sensor 12 may be disposed in a deposition chamber CH that is described below. The sensor 12 may detect the amount of deposition material provided from the deposition source 40 to the substrate SUB.

In an embodiment, the sensor 12 may be a quartz crystal microbalance (QCM) sensor. The quartz crystal microbalance may detect frequency characteristics. The frequency characteristic may change in case that the deposition material is deposited on a surface of the quartz crystal microbalance. For example, in case that the deposition material is deposited on the surface of the quartz crystal microbalance, the frequency characteristics of the crystal may be changed. The change in the frequency characteristic may be defined as a function of the thickness and density of the deposition material. The thickness of the deposition film DL on the substrate SUB, the thickness deposited per unit time, or the like may be calculated by detecting the change in the frequency characteristic. A power supply amount of the heater 600 included in the deposition source 40 may be controlled by the change in the frequency characteristic.

The number of sensors 12 may be plural. For example, in case that there are multiple deposition sources 40, the sensor 12 may be disposed for each deposition source 40. Accordingly, each deposition source 40 may be more accurately controlled than using one sensor 12.

As a life of the QCM increases (i.e., as the sensor 12 is used), an accuracy of detecting the change in the frequency characteristic may decrease. To prevent this, multiple sensors 12 may be disposed in the deposition chamber CH. The change in the frequency characteristic may be expressed as the life. For example, it may be expressed that 1 life increases whenever about 0.015 MHz decreases based on a fundamental frequency of the quartz crystal microbalance. The fundamental frequency may be about 6 MHz (megahertz).

Multiple sensors 12 may be disposed in the chamber CH in consideration of a lifespan of the sensor 12.

The rate calculator 14 may be connected to sensor 12. The rate calculator 14 may 14 may calculate the first deposition rate based on the amount of the deposition material provided to the substrate SUB. For example, the rate calculator 14 may calculate the first deposition rate based on the change in the frequency characteristic detected by the sensor 12.

However, the disclosure is not limited thereto. For example, the monitoring part 10 may include various components that calculate the deposition rate, and the components may be connected in various ways.

The control part 20A may control the deposition rate. In an embodiment, the control part 20A may include a filter 22A, a first controller 24, and a second controller 26. In an embodiment, the control part 20A of FIG. 1 and the filter 22A may be implemented with a same device.

In an embodiment, the filter 22A may be a median filter. The median filter may be a non-linear filter. For example, the median filter may remove noise. Noise may be defined as a value outside of a predetermined range from a median of values obtained by sampling the first deposition rates V1. For example, the predetermined range may be set within about 2% (percent) from the median value. However, the disclosure is not limited thereto. For example, the predetermined range may vary in consideration of final film thickness, monitoring rate, or the like.

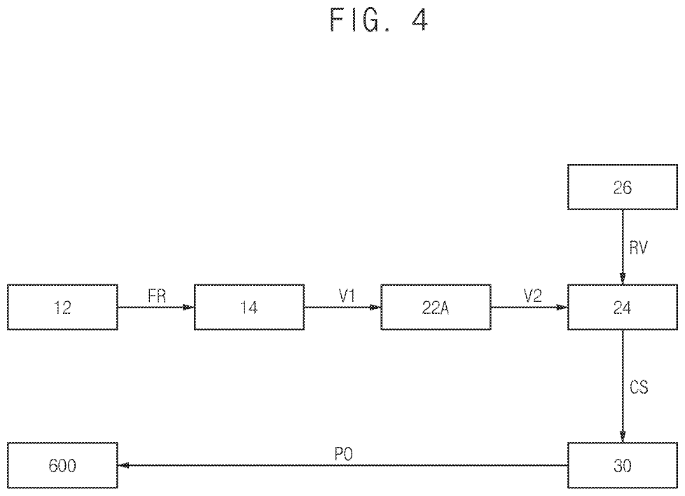

In an embodiment, the filter 22A may perform a noise removal process in case that the first deposition rate is out of the predetermined range. For example, in case that the sampling values of the first deposition rate satisfy the predetermined range from the median value, the filter 22A may omit the noise removal process. On the other hand, in case that the sampling values of the first deposition rate deviate from the median value outside of the predetermined range (i.e., if the noise exists), the filter 22A may perform the noise removal process. The filter 22A may provide a second deposition rate (e.g., a second deposition rate V2 of FIG. 4) that the noise is removed from the first deposition rate.

The first controller 24 may provide a control signal (e.g., a control signal CS of FIG. 3) based on the deposition rate (e.g., the first deposition rate or the second deposition rate).

In an embodiment, the first controller 24 may be a proportional integral derivative (PID) controller. The PID-type controller may perform a PID operation and output an operation value (i.e., the control signal). For example, the PID-type controller may calculate an amount of manipulation using a set value and a measured value. For example, the set value may be a reference rate (e.g., a reference rate RV of FIG. 3). The measured value may be the first deposition rate. The amount of manipulation may correspond to an amount of power supplied to the heater 600.

In case that the measured value is smaller than the set value, the PID-type controller may control the amount of manipulation to increase. On the other hand, in case that the measured value is greater than the set value, the PID-type controller may control the amount of manipulation to decrease.

For example, the PID-type controller may compare the reference rate with the first deposition rate and control the deposition rate so that the first deposition rate converges with the reference rate. The deposition rate may be controlled by the amount of power provided to the heater 600. For example, the deposition rate may increase as the amount of power supplied to the heater 600 increases, and the deposition rate may decrease as the amount of power provided to the heater 600 decreases.

The PID-type controller may control the amount of change in the amount of manipulation to increase as a difference between the reference rate and the first deposition rate increases. For example, as the difference between the reference rate and the first deposition rate increases, the amount of change in the amount of power provided to the heater 600 may increase.

In an embodiment, in case that the first deposition rate is out of the predetermined range, the second deposition rate may be provided by the filter 22A. As described above, the second deposition rate V2 may be obtained by processing the noise removal from the first deposition rate V1, and the first controller 24 may provide the control signal based on the second deposition rate V2.

In another embodiment, in case that the first deposition rate is within the predetermined range, the first controller 24 may provide the control signal based on the first deposition rate V1.

A control system of a deposition source according to a comparative embodiment may not include the filter 22A. The first controller 24 may provide a control signal based on the first deposition rate including noise. Accordingly, the control system of the deposition source according to the comparative embodiment may control to apply an excessive amount of power or an insufficient amount of power to the heater 600. For this reason, in a deposition apparatus including the control system of deposition source according to the comparative embodiment, thickness distribution of the deposition film may be large. As the thickness distribution of the deposited film increases, a quality of a display device may deteriorate. For example, in case that the thickness of the deposited film deviates from a resonance thickness, a display quality of the display device may deteriorate. For example, as the thickness of the deposition film increases, the thickness of the display device increases, and manufacturing costs may increase due to material waste. On the other hand, in case that the deposited film is too thin, the deposited film may not perform its function. For example, in case that the deposited film is a hole transport layer, in case that the hole transport layer is formed too thin, a probability of exciton formation may decrease.

On the other hand, the control system 1A of the deposition source 40 according to an embodiment of the disclosure may include the filter 22A. The filter 22A may remove the noise in case that the first deposition rate is out of a predetermined range. Accordingly, the control system 1A of the deposition source 40 according to an embodiment of the disclosure may provide a stabilized control signal. In other words, the control system 1A of the deposition source 40 may provide the control signal based on the first deposition rate V1 in case that the first deposition rate is within the predetermined range, and the control system 1A of the deposition source 40 may provide the control signal based on the second deposition rate V2 in case that the first deposition rate is out of the predetermined range. Accordingly, the control system 1A of the deposition source 40 according to an embodiment of the disclosure may control the amount of power provided to the heater 600 so that the film is formed close to the set final film thickness.

In an embodiment, the second controller 26 may be a programmable logic controller (PLC). The programmable logic controller may record data (e.g., the reference rate RV of FIG. 3) required for the PID operation, data output through the PID operation, or the like. The programmable logic controller may provide the data required for the PID operation to the PID-type controller.

However, the disclosure is not limited thereto. For example, the control part 20A may include various components that control the deposition rate, and the components may be connected in various ways.

The power supply 30 may be controlled by the first controller 24. For example, the first controller 24 may output a control signal CS based on the deposition rate (e.g., the first deposition rate V1 or the second deposition rate V2). The power supply 30 may output power corresponding to the control signal CS. The power may be provided to the heater 600 included in the deposition source 40.

The deposition source 40 may be disposed in the deposition chamber CH, and the deposition source 40 may be connected to the control system 1A of the deposition source 40. The connection may include all connection methods such as electrical connection, functional connection, physical connection, or the like.

The deposition chamber CH may provide a space for performing a deposition process. The deposition chamber CH may be connected to a vacuum pump. The vacuum pump may control an internal pressure of the deposition chamber CH and may discharge materials not deposited on the substrate SUB to the outside of the deposition chamber CH.

The deposition chamber CH may have a rectangular shape. However, the disclosure is not limited thereto. The deposition chamber CH may have various shapes to perform the deposition process. For example, the deposition chamber CH may have various shapes such as a circular shape, a polygonal shape, or the like.

A substrate fixing device 100 and the deposition source 40 may be disposed in the deposition chamber CH. The deposition source 40 may be a vertical deposition source. The substrate fixing device 100 may be disposed on a first side of the deposition chamber CH, and the deposition source 40 may be disposed on a second side of the deposition chamber CH. The first side and the second side of the deposition chamber CH may face each other. For example, the substrate fixing device 100 and the deposition source 40 may face each other in a first direction DR1.

However, the disclosure is not limited thereto. For example, the deposition source 40 may be a horizontal deposition source. The substrate fixing device 100 and the deposition source 40 may face each other in a second direction DR2. The second direction DR2 may intersect the first direction DR1. For example, the second direction DR2 may be perpendicular to the first direction DR1, and the second direction DR2 may be a direction of gravity.

The substrate fixing device 100 may fix the substrate SUB moved into the deposition chamber CH. For example, the substrate SUB may be disposed between the substrate fixing device 100 and the deposition source 40 in the deposition chamber CH, and the substrate SUB may be fixed in the deposition chamber CH by the substrate fixing device 100. For example, in a cross-sectional view, the substrate fixing device 100 may extend in the second direction DR2, and a length of the substrate fixing device 100 in the second direction DR2 may be greater than a length of the substrate SUB in the second direction DR2. Accordingly, the substrate SUB may be stably fixed. For example, the substrate fixing device 100 may be an electrostatic chuck.

The deposition source 40 may store the deposition material, heat the deposition material, and spray the deposition material toward the substrate SUB. Accordingly, the deposition film DL may be formed on the substrate SUB. The deposition source 40 may include a nozzle member 300, a connecting member 400, a vaporizing member 500, and the heater 600.

The nozzle member 300 may be connected to the vaporizing member 500. For example, the nozzle member 300 may be connected to the vaporizing member 500 through the connecting member 400. For example, the nozzle member 300 and the vaporizing member 500 may be spaced apart from each other.

The nozzle member 300 may include multiple nozzles. Each of the nozzles may include a body and an ejecting part. The body may be disposed within a housing. The ejecting part may have a shape protruding from the body and may protrude from a surface of the housing toward the substrate SUB. Each of the ejecting parts may be spaced apart from each other. For example, each of the ejecting parts may be arranged with an equal interval in the second direction DR2 or may be arranged with irregular intervals in the second direction DR2. In case that the deposition material is sprayed from the ejecting part, the deposition material may be provided to the substrate SUB.

Each of the nozzles may include a heat-resistant material. For example, each of the nozzles may include a heat-resistant material such as metal, alloy, ceramic, glass, or the like. These may be used alone or in combination with each other. The body and the ejecting part may include a same material or may include different materials.

The connecting member 400 may connect the nozzle member 300 and the vaporizing member 500 to each other. Accordingly, the connecting member 400 may provide a space in which the deposition material provided from the vaporizing member 500 moves to the nozzle member 300. For example, in the cross-sectional view, the connection member 400 may have a shape extending in the second direction DR2.

The connecting member 400 may include a heat-resistant material. For example, the connecting member 400 may include a heat-resistant material such as metal, alloy, ceramic, glass, or the like. These may be used alone or in combination with each other. The connecting member 400 may include various heat-resistant materials.

The vaporizing member 500 may include a body part 510 and a cover part 520. A container 515 may be accommodated in the body part 510. The container 515 may store a deposition material. For example, in the cross-sectional view, the container 515 may have a rectangular shape with an open top. The cover part 520 may be disposed on the body part 510. For example, the cover part 520 may cover an upper surface of the container 515.

The vaporizing member 500 may include a heat-resistant material. For example, the vaporizing member 500 may include a metal, alloy, ceramic, glass, carbon material, or the like. These may be used alone or in combination with each other. However, the disclosure is not limited thereto. The vaporizing member 500 may include various heat-resistant materials.

The heater 600 may be disposed adjacent to the vaporizing member 500. For example, the heater 600 may surround a side of the vaporizing member 500. However, the disclosure is not limited thereto. The heater 600 may be disposed in various positions and heat the vaporizing member 500.

The heater 600 may heat the vaporizing member 500. Accordingly, the deposition material stored in the vaporizing member 500 may be vaporized (or sublimated). The vaporized (or sublimated) deposition material may move to the nozzle member 300 through the connection member 400, and the nozzle member 300 may spray the deposition material toward the substrate SUB.

The heater 600 may be connected to the power supply 30. The power supply 30 may supply power to the heater 600. A vaporization amount (or a sublimation amount) of the deposition material may be controlled according to the amount of power provided to the heater 600. For example, as an amount of power increases, the vaporization amount (or the sublimation amount) may increase, and as an amount of power decreases, the vaporization amount (or the sublimation amount) may decrease.

The deposition material may be a material that may be vaporized by heat. In an embodiment, the deposition material may include an organic material. For example, the organic material may include an emission material, a hole injection material, a hole transport material, an electron injection material, an electron transport material, or the like.

The emission material may include anthracene, phenyl-substituted cyclopentadiene, perylene, tris-aluminum, or the like. These may be used alone or in combination with each other. However, the disclosure is not limited thereto. The emission material may include various materials that emit light having a color. For example, the color may be one of red, blue, or green.

The hole injection material may include copper phthalocyanine (CuPc), PEDOT: PSS (poly (3,4,-ethylene dioxythiophene): poly (styrene sulfonate)), or the like. These may be used alone or in combination with each other. However, the disclosure is not limited thereto. The hole injection material may include various materials that facilitate hole injection from an anode electrode.

The hole transport material may include an aromatic amine or the like. These may be used alone or in combination with each other. However, the disclosure is not limited thereto. The hole transport material may include various materials that readily transport holes and confine electrons to the emission region to increase the probability of exciton formation.

The electron transport material may include a compound including an electron attracting body and a metal compound that accepts the electrons. For example, the electron transport material may include a compound including a functional group that may attract the electrons by resonance, such as cyan group, oxadiazole, triazole, tris-aluminum, or the like. These may be used alone or in combination with each other. However, the disclosure is not limited thereto. The electron transport material may include various materials that stabilize anion radicals generated in case that the electrons are injected from a cathode electrode.

The electron injection material may include a metal having electron affinity. However, the disclosure is not limited thereto. The electron injection material may include various materials that facilitate the electron injection from the cathode electrode.

FIG. 3 is a schematic block diagram illustrating an operation of the control system of the deposition source according to an embodiment. FIG. 4 is a schematic block diagram illustrating an operation of the control system of the deposition source according to another embodiment.

For example, FIG. 3 schematically illustrate the operation of the control system 1A of the deposition source 40 that controls the deposition source 40 based on a first deposition rate V1, in case that the first deposition rate V1 is within the predetermined range. FIG. 4 schematically illustrate the operation of the control system 1A of the deposition source 40 that controls the deposition source 40 based on a second deposition rate V2 from which the noise is removed from the first deposition rate V1, in case that the first deposition rate V1 is out of the predetermined range. Hereinafter, repetitive descriptions with respect to those of the control system 1A of the deposition source 40 described above with reference to FIGS. 1 and 2 will be omitted or simplified.

Referring to FIG. 3, the sensor 12 may detect the change in frequency characteristics FR. As described above with reference to FIGS. 1 and 2, in an embodiment, the sensor 12 may be a QCM. The QCM may detect the change in frequency characteristics FR according to the deposition material.

The rate calculator 14 may calculate the first deposition rate V1 based on the change in frequency characteristics FR. The first deposition rate V1 may include noise.

In case that the noise has little or no effect on a rate-based control, the first controller 24 may generate the control signal CS based on the first deposition rate V1. For example, in case that sampling value is within about 2% from the median value of the first deposition rate V1, the filter 22A may not process a noise removal.

In an embodiment, the first controller 24 may be a PID-type controller. For example, the first controller 24 may compare the reference rate RV and the first deposition rate V1, and generate a control signal CS to converge the first deposition rate V1 to the reference rate RV. The reference rate RV may be stored in the second controller 26. For the PID operation, the reference rate RV may be provided from the second controller 26 to the first controller 24. In an embodiment, the first deposition rate V1 may be stored in the second controller 26.

The power supply 30 may provide power PO based on the control signal CS generated based on the first deposition rate V1. For example, the power supply 30 may provide power PO to the heater 600 included in the deposition source (e.g., the deposition source 40 of FIG. 1) based on the control signal CS. A temperature of the heater 600 may be controlled by an amount of power PO supplied from the power supply 30. For example, as an amount of the power PO supplied from the power supply 30 increases, the temperature of the heater 600 may increase.

The operation of the control system of deposition source 1A of FIG. 4 may differ from the operation of the control system of deposition source 1A of FIG. 3 only in that the operation of the deposition source control system 1A passes through the filter 22A. Hereinafter, repetitive descriptions with respect to those of the control system 1A of the deposition source 40 described above with reference to FIG. 3 will be omitted or simplified.

Referring to FIG. 4, the sensor 12 may detect the change in frequency characteristics FR. In an embodiment, the sensor 12 may be a QCM.

The rate calculator 14 may calculate the first deposition rate V1 based on the change in frequency characteristics FR. The first deposition rate V1 may include noise.

In case that the noise affects the rate-based control, the noise of the first deposition rate V1 calculated by the first controller 24 may be removed by the filter 22A. For example, in case that the sampling values are outside of about 2% from the median value of the first deposition rate V1, the filter 22A may process the noise removal.

In an embodiment, the filter 22A may be a median filter. The median filter may remove noise. Noise may be defined as a value outside of a predetermined range from the median of values obtained by sampling the first deposition rates V1. For example, a value outside of about 2% from the median value of the first deposition rate V1 may be removed as a noise. Accordingly, the second deposition rate V2 may be calculated by removing the noise from the first deposition rate V1.

The first controller 24 may generate a control signal CS based on the second deposition rate V2. In an embodiment, the first controller 24 may be a PID-type controller. For example, the first controller 24 may compare the reference rate RV and the second deposition rate V2, and provide a control signal CS corresponding to the second deposition rate V2 that converges to the reference rate RV.

The reference rate RV may be stored in the second controller 26. For the PID-operation, the reference rate RV may be provided from the second controller 26 to the first controller 24. In an embodiment, the first deposition rate V1 and the second deposition rate V2 may be stored in the second controller 26.

The power supply 30 may provide power PO based on the control signal CS generated based on the second deposition rate V2. For example, the power supply 30 may provide power PO to the heater 600 included in the deposition source 40 based on the control signal CS. The temperature of the heater 600 may be controlled by an amount of power PO supplied from the power supply 30. For example, as an amount of the power PO supplied from the power supply 30 increases, the temperature of the heater 600 may increase.

In summary, in case that the first deposition rate V1 is outside of the predetermined range, the control signal CS may be provided based on the second deposition rate V2 provided by the filter 22A. On the other hand, in case that the first deposition rate V1 is within the predetermined range, the control signal CS may be provided based on the first deposition rate V1.

The control system 1A of the deposition source 40 according to an embodiment of the disclosure may include the filter 22A. Accordingly, the deposition source 40 may be controlled based on the second deposition rate V2 from which noise is removed. For example, the temperature of the heater 600 included in the deposition source 40 may be controlled based on the second deposition rate V2 from which noise is removed. As a result, the thickness distribution of the deposition film (e.g., the deposition film DL of FIG. 2) included in the display device may be reduced to less than about 1%, and thus the quality of the display device may be improved.

The filter 22A included in the control system 1A of the deposition source 40 may remove noise only in case that the first deposition rate V1 is outside of the predetermined range. Accordingly, the control system 1A of the deposition source 40 may prevent a control delay due to a noise removal process.

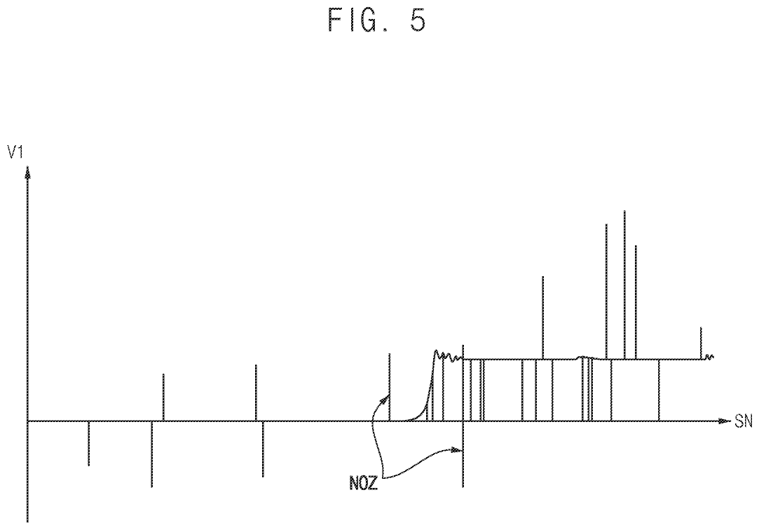

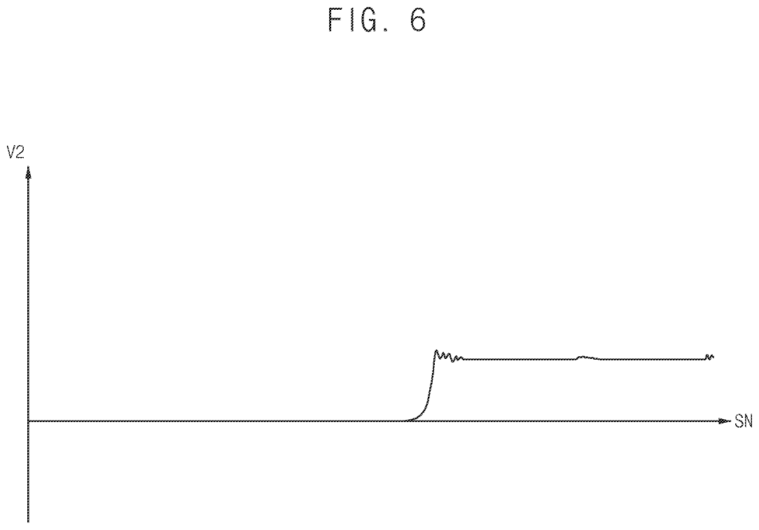

FIG. 5 is a graph illustrating the first deposition rate provided by the rate calculator included in the control system of the deposition source of FIG. 1. FIG. 6 is a graph illustrating the second deposition rate provided by the filter included in the control system of the deposition source of FIG. 1.

Referring to FIGS. 1, 5, and 6, X-axis values are sampling sequences SN, and Y-axis values are deposition rates V1 and V2 depending on the sampling sequences SN.

As shown in FIG. 5, a noise NOZ may be included in the first deposition rate V1. Noise NOZ may be a data that is excessively large or excessively low compared to an actual deposition rate. Therefore, in case that the control system 1A controls the deposition source 40 based on the first deposition rate V1 including noise NOZ, excessive or insufficient voltage may be applied to the heater 600.

As shown in FIG. 6, noise NOZ may not be included in the second deposition rate V2. For example, the second deposition rate V2 may be obtained by removing noise NOZ from the first deposition rate V1. For example, noise NOZ may be a data outside of about 2% of the median value of the first deposition rate V1. However, the disclosure is not limited thereto. For example, the range of data removed as a noise NOZ may vary depending on a type of deposition process, process time, or the like.

The second deposition rate V2 may be closer to the actual deposition rate than the first deposition rate V1. For this reason, the heater 600 may be more precisely controlled in case that the heater 600 is controlled based on the second deposition rate V2 than in case that the heater 600 is controlled based on the first deposition rate V1.

In FIGS. 5 and 6, the first deposition rate V1 may include noise NOZ outside of the predetermined range that has been described, however, the disclosure is not limited thereto. For example, in case that the first deposition rate V1 is within the predetermined range, the heater 600 included in the deposition source 40 may be controlled based on the first deposition rate V1.

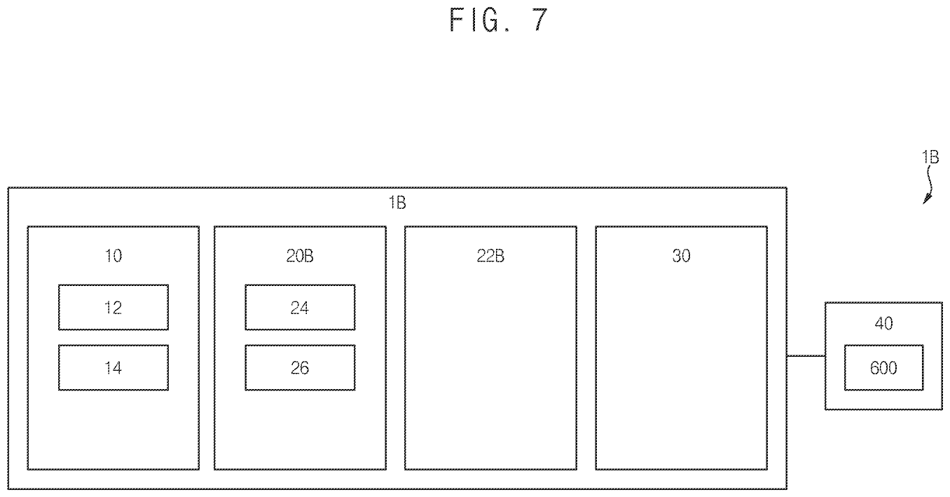

FIG. 7 is a schematic block diagram of a control system of the deposition source according to another embodiment of the disclosure.

Referring to FIG. 7, a control system 1B of the deposition source 40 according to another embodiment of the disclosure may include a deposition source 40, a monitoring part 10 connected to the deposition source 40, a control part 20B, a filter 22B, and the power supply 30. For example, the control system 1B of the deposition source 40 of FIG. 7 may be different from the control system 1A of the deposition source 40 of FIG. 1 only in the configuration of the control part 20B and the filter 22B, and other components may be substantially the same (or similar). For example, the control part 20A and the filter 22A of FIG. 1 may be implemented in a same device, and the control part 20B and the filter 22B of FIG. 7 may be implemented in different devices. Hereinafter, repetitive descriptions with respect to those of the control system 1A of the deposition source 40 described above with reference to FIGS. 1, 2, 3, 4, 5, and 6 will be omitted or simplified.

The monitoring part 10 may detect the first deposition rate (e.g., the first deposition rate V1 of FIG. 3). The monitoring part 10 may include a sensor 12 and a rate calculator 14.

The sensor 12 may be a QCM. The QCM may detect the change in the frequency characteristics in case that the deposition material is deposited on the surface of the quartz crystal microbalance. In an embodiment, the number of sensors 12 may be plural. For example, in case that there are multiple deposition sources 40, the sensor 12 may be disposed for each deposition source 40.

The rate calculator 14 may be connected to sensor 12. The rate calculator 14 may calculate the first deposition rate V1 based on the change in the frequency characteristic detected by the sensor 12.

As described above, the monitoring part 10 may include various components that calculate the deposition rate, and the components may be connected in various ways.

The control part 20B may control the deposition rate. In an embodiment, the control part 20B may include a first controller 24 and a second controller 26. For example, the control part 20B and the filter 22B of FIG. 7 may be implemented in different devices.

In an embodiment, the filter 22B may be a median filter. The median filter may be a non-linear filter that, after sampling the first deposition rate, selects a median value of the sampling values of the first deposition rates and removes a value outside of a predetermined range from the median value as a noise. For example, the predetermined range may be about 2% from the median value. However, the disclosure is not limited thereto. For example, the predetermined range may vary in consideration of the final film thickness, the monitoring rate, or the like.

In an embodiment, the filter 22B may remove noise in case that the first deposition rate V1 is outside of the predetermined range. In other words, in case that the sampling values of the first deposition rate is within the predetermined range, the filter 22B may not process the noise removal. On the other hand, in case that the sampling value of the first deposition rate is outside of the predetermined range, the filter 22B may process the noise removal. Accordingly, the filter 22B may provide a second deposition rate (e.g., the second deposition rate V2 of FIG. 4) obtained by the removing noise from the first deposition rate V1.

In an embodiment, the first controller 24 may be a PID-type controller. For example, the first controller 24 may provide a control signal CS based on the deposition rate (e.g., the first deposition rate V1 or the second deposition rate V2).

In an embodiment, in case that the first deposition rate V1 is outside of the predetermined range, the second deposition rate V2 may be provided by the filter 22B. As described above, the second deposition rate V2 may be obtained by processing a noise removal from the first deposition rate V1. The first controller 24 may provide a control signal CS based on the second deposition rate V2.

In another embodiment, in case that the first deposition rate is within the predetermined range, the first controller 24 may provide the control signal CS based on the first deposition rate V1.

In an embodiment, the second controller 26 may be a PLC. The PLC may record the data required for the PID operation, the data output through the PID operation, or the like. The PLC may provide the data required for the PID operation to the PID-type controller.

However, the disclosure is not limited thereto. For example, the control part 20B may include various components that control the deposition rate, and the components may be connected in various ways.

The power supply 30 may be controlled by the first controller 24. For example, the first controller 24 may output a control signal CS based on the deposition rate (e.g., the first deposition rate V1 or the second deposition rate V2). The power supply 30 may output power corresponding to the control signal CS. The power may be provided to the heater 600 included in the deposition source 40.

The control system 1B of the deposition source 40 according to another embodiment of the disclosure may include the filter 22B. Accordingly, the deposition source 40 may be controlled based on the second deposition rate V2 from which the noise is removed. For example, the temperature of the heater 600 included in the deposition source 40 may be controlled based on the second deposition rate V2 from which the noise is removed. As a result, the thickness distribution of the deposition film DL included in the display device may be reduced to less than about 1%, and thus the quality of the display device may be improved.

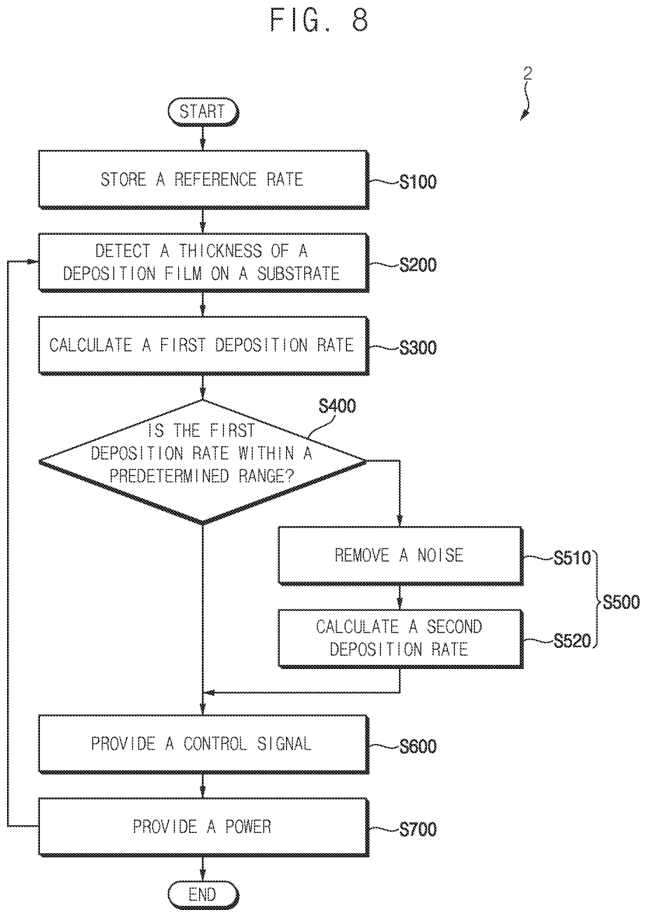

FIG. 8 is a flowchart of the control method of the deposition source using the control system of the deposition source according to embodiments of the disclosure.

Referring to FIGS. 1, 3, 4, 7, and 8, a control method 2 of a deposition source 40 using the control system 1A or 1B of the deposition source 40 according to embodiments of the disclosure may include the following steps. Hereinafter, repetitive descriptions with respect to those of the control systems 1A and 1B of the deposition source described above with reference to FIGS. 1, 2, 3, 4, 5, 6, and 7 will be omitted or simplified.

The reference rate RV may be stored (S100). The reference rate RV may be a data stored for the PID operation. In an embodiment, the reference rate RV may be stored in the second controller 26. As described above, the second controller 26 may store the data required for the PID operation.

The amount of the deposition material provided to the substrate (e.g., the substrate SUB of FIG. 2) from the deposition source 40 may be detected (S200). The amount of the deposition material may be detected by the sensor 12. In an embodiment, sensor 12 may be a QCM. The QCM may detect the change in the frequency characteristics FR caused by the deposition material.

The first deposition rate V1 may be calculated (S300). The first deposition rate V1 may be calculated based on the output value of the sensor 12. For example, the first deposition rate V1 may be calculated based on the change in the frequency characteristic FR of the QCM. In an embodiment, the first deposition rate V1 may be provided from rate calculator 14 to the filters 22A or 22B or the first controller 24.

It is determined whether the first deposition rate V1 is within the predetermined range (S400). The predetermined range may be different for each deposition process. For example, the deposition quality may be improved as the predetermined range is narrow, however, a deposition process time may increase due to the control of the deposition source 40. On the other hand, as the predetermined range increases, the deposition process time delay due to the control of the deposition source 40 may decrease, however, a degree of improvement of deposition quality may also decrease.

In case that the first deposition rate V1 is outside of the predetermined range, a step of removing noise (e.g., the noise NOZ of FIG. 5) from the first deposition rate V1 may be performed (S510). Through this, the second deposition rate V2 from which the noise is removed from the first deposition rate V1 may be calculated (S520). For example, the noise removal process and calculating the second deposition rate V2 (S500) may be performed only in case that the first deposition rate V1 is outside of the predetermined range. Accordingly, the control delay according to the noise removal process (S510) may be prevented. In an embodiment, the noise removal process and the calculating of the second deposition rate V2 (S500) may be performed by the filter 22A or 22B.

The control signal CS may be provided (S600). The control signal CS may be provided from the first controller 24 to the power supply 30.

Power PO may be provided. The power PO may be provided from the power supply 30 to the heater 600 included in the deposition source 40.

A control method of the deposition source according to a comparative embodiment may not include the noise removal process (S510). The control signal may be provided based on the first deposition rate V1 including noise (S600). Accordingly, the thickness distribution of the deposition film formed by the control method of the deposition source according to the comparative embodiment may be large.

On the other hand, the control method 2 of the deposition source 40 using the control system 1A or 1B of the deposition source 40 according to embodiments of the disclosure may include the noise removal process (S510). Accordingly, the deposition source 40 may be controlled based on the second deposition rate V2 from which noise is removed. In other words, the temperature of the heater 600 included in the deposition source 40 may be controlled based on the second deposition rate V2 from which noise is removed. Accordingly, the deposition film DL formed by the control method 2 of the deposition source 40 using the control system 1A or 1B of the deposition source 40 according to embodiments of the disclosure may have a small thickness distribution.

In the control method 2 of the deposition source 40, the noise removal process (S510) may be performed only in case that the first deposition rate V1 is outside of the predetermined range. Accordingly, the control delay due to the noise removal process (S510) may be prevented.

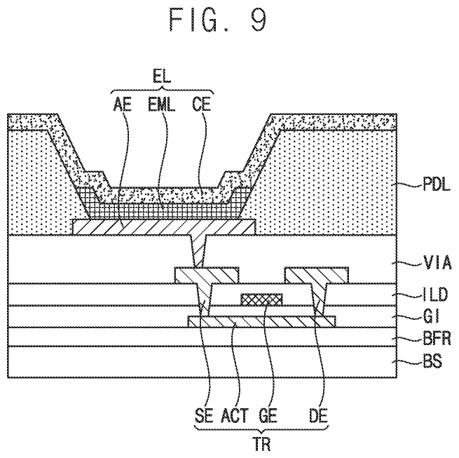

FIG. 9 is a schematic cross-sectional view illustrating a pixel formed by the deposition process using the deposition apparatus including the control system 1A or 1B of the deposition source 40 according to embodiments of the disclosure.

Referring to FIG. 9, a pixel PX may include a base substrate BS, a buffer layer BFR, a transistor TR, a gate insulating layer GI, an interlayer insulating layer ILD, a via insulating layer VIA, an emission device EL, and a pixel defining layer PDL.

The transistor TR may include an active layer ACT, a gate electrode GE, a source electrode SE, and a drain electrode DE. The emission device EL may include a first electrode AE, an emission layer EML, and a second electrode CE.

The base substrate BS may include glass, quartz, plastic, or the like. For example, the base substrate BS may have flexible, bendable, or rollable characteristics.

The buffer layer BFR may be disposed on the base substrate BS. The buffer layer BFR may include an inorganic insulating material. For example, the buffer layer BFR may include silicon oxide, silicon nitride, silicon oxynitride, or the like. The buffer layer BFR may block impurities so that the active layer ACT of the transistor TR is not damaged by the impurities diffused through the base substrate BS.

The active layer ACT may be disposed on the buffer layer BFR. In an embodiment, the active layer ACT may include a silicon semiconductor. For example, the active layer ACT may include amorphous silicon, polycrystalline silicon, or the like. In another embodiment, the active layer ACT may include an oxide semiconductor. For example, the active layer ACT may include zinc oxide, zinc-tin oxide, zinc-indium oxide, indium oxide, titanium oxide, indium-gallium-zinc oxide, indium-zinc-tin oxide, or the like.

The gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, tantalum oxide, or the like. The gate insulating layer GI may electrically insulate the active layer ACT and the gate electrode GE from each other.

The gate electrode GE may be disposed on the gate insulating layer GI. The gate electrode GE may include a conductive material. For example, the gate electrode GE may include a metal, an alloy, a conductive metal oxide, a transparent conductive material, or the like. A gate signal may be applied to the gate electrode GE. The gate signal may turn on/off the transistor TR to adjust electrical conductivity of the active layer ACT.

The interlayer insulating layer ILD may be disposed on the gate electrode GE. The interlayer insulating layer ILD may include an organic insulating material and/or an inorganic insulating material. The interlayer insulating layer ILD may electrically insulate the source electrode SE and drain electrode DE from the gate electrode GE.

The source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, a transparent conductive material, or the like. Each of the source electrode SE and the drain electrode DE may electrically contact the active layer ACT through a contact hole (or contact opening) passing through the interlayer insulating layer ILD and the gate insulating layer GI.

The via insulating layer VIA may be disposed on the source electrode SE and the drain electrode DE. The via insulating layer VIA may include an organic insulating material. For example, the via insulating layer VIA may include a polyacrylic resin, a polyimide resin, an acrylic resin, or the like. Accordingly, an upper surface of the via insulating layer VIA may be substantially flat.

The first electrode AE may be disposed on the via insulating layer VIA. The first electrode AE may include a conductive material. For example, the first electrode AE may include a metal, an alloy, a conductive metal oxide, a transparent conductive material, or the like. The first electrode AE may electrically contact the source electrode SE or the drain electrode DE through a contact hole (or contact opening) penetrating the via insulating layer VIA.

The pixel defining layer PDL may be disposed on the first electrode AE. The pixel defining layer PDL may include an organic insulating material. For example, the pixel defining layer PDL may include a polyacryl-based compound, a polyimide-based compound, or the like. The pixel defining layer PDL may partition the emission region of each of the pixels. The pixel defining layer PDL may include a pixel opening exposing the first electrode AE.

The emission layer EML may be disposed on the first electrode AE in the pixel opening. The emission layer EML may include an organic emission material. In an embodiment, the emission layer EML may have a multi-layer structure including various functional layers. For example, the emission layer EML may include at least one of a hole injection layer, a hole transport layer, an electron transport layer, and an electron injection layer.

The second electrode CE may be disposed on the emission layer EML and may cover the pixel defining layer PDL.

In an embodiment, the emission layer EML may be formed by depositing a deposition material on the first electrode AE. For example, the emission layer EML may be formed by a deposition method (e.g., a deposition method including the control method 2 of the deposition source 40 of FIG. 8) using the deposition apparatus (e.g., the deposition apparatus including the control system 1A of the deposition source 40 of FIG. 1 or the control system 1B of the deposition source 40 of FIG. 7).

However, the disclosure is not limited thereto, and a layer formed through the deposition process may be functional layers, such as the hole transport layer, the electron transport layer, or the like. In another embodiment, the layer formed through the deposition process may be a capping layer, an encapsulation layer disposed on the second electrode CE, or the like

As described above, the layer formed through the deposition process may have a small thickness distribution by forming the deposition apparatus including the control system 1A of the deposition source 40 of FIG. 1 or the control system 1B of the deposition source 40 of FIG. 7. As a result, the display quality of the display device including the pixel on which the deposition process is completed may be improved.

The disclosure may be applied to a manufacturing process of various display devices included in a computer, a notebook, a cell phone, a smart phone, a PMP, a PDA, a MP3 player, or the like.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A control system of a deposition source comprising:
a deposition source that includes a heater and provides a deposition material to a substrate;
a sensor that detects an amount of the deposition material provided to the substrate;
a rate calculator that calculates a first deposition rate based on the amount of the deposition material provided to the substrate; and
a filter that calculates a second deposition rate by removing a noise from the first deposition rate.

2. The control system of the deposition source of claim 1, wherein the sensor is a quartz crystal microbalance (QCM).

3. The control system of the deposition source of claim 1, wherein the filter is a median filter.

4. The control system of the deposition source of claim 1, wherein the filter removes the noise in case that the first deposition rate is outside of a predetermined range.

5. The control system of the deposition source of claim 4, further comprising:
a first controller that generates a control signal based on the second deposition rate.

6. The control system of the deposition source of claim 5, wherein the first controller is a proportional integral derivative (PID) control-type controller.

7. The control system of the deposition source of claim 5, wherein the control signal controls an amount of power supplied to the heater.

8. The control system of the deposition source of claim 5, wherein the filter and the first controller are implemented in a same device.

9. The control system of the deposition source of claim 5, further comprising:
a second controller that stores a reference rate and provides the reference rate to the first controller.

10. The control system of the deposition source of claim 9, wherein the second controller is a programmable logic controller (PLC).

11. A control system of a deposition source comprising:
a deposition source that includes a heater and provides a deposition material to a substrate;
a sensor that detects an amount of the deposition material provided to the substrate;
a rate calculator that calculates a first deposition rate based on the amount of the deposition material provided to the substrate;
a filter that calculates a second deposition rate by removing a noise from the first deposition rate; and
a first controller that compares the second deposition rate with a reference rate and generates a control signal controlling an amount of power supplied to the heater.

12. The control system of the deposition source of claim 11, wherein the sensor is a quartz crystal microbalance (QCM).

13. The control system of the deposition source of claim 11, wherein the filter is a median filter.

14. The control system of the deposition source of claim 11, wherein the filter removes the noise in case that the first deposition rate is outside of a predetermined range.

15. The control system of the deposition source of claim 14, wherein the first controller generates the control signal based on the second deposition rate in case that the first deposition rate is outside of the predetermined range.

16. The control system of the deposition source of claim 14, wherein the first controller generates the control signal based on the first deposition rate in case that the first deposition rate is within the predetermined range.

17. The control system of the deposition source of claim 11, wherein the first controller is a proportional integral derivative (PID) control-type controller.

18. The control system of the deposition source of claim 11, wherein the filter and the first controller are implemented in a same device.

19. The control system of the deposition source of claim 11, further comprising:
a second controller that stores the reference rate and provides the reference rate to the first controller.

20. The control system of the deposition source of claim 19, wherein the second controller is a programmable logic controller (PLC).
